(19) United States
(12) Patent Application Publication
(10) Pub. No.: US 2002/0051511 A1
(43) Pub. Date: May 2, 2002

(54) Video apparatus having serial receiver

(75) Inventor: Tohru Kataoka, Tokyo (JP)

Correspondence Address: SUGHRUE, MION, ZINN, MACPEAK & SEAS, 2100 Pennsylvania Avenue, N.W., Washington, DC, 20037, US

(73) Assignee: NEC VIEWTECHNOLOGY, LTD.

(21) Appl. No.: 09/978,552

(22) Filed: Oct. 18, 2001

(30) Foreign Application Priority Data
Oct. 31, 2000 (JP) 337274/2000

(51) Int. Cl. H03D 3/24

(52) U.S. Cl. 375/376

(57) ABSTRACT

There is disclosed a video apparatus, comprising: a serial receiver for receiving, reproducing and outputting a serially transmitted synchronous clock, a control signal, and a signal containing video data; and a phase locked loop (PLL) for generating a differential clock having a phase different from that of the signal input from the serial receiver, and a main clock having a phase different from that of the signal input from the serial receiver, and a frequency twice as much as that of the differential clock, based on the signal input from the serial receiver. It is possible to set optimal timing for a clock signal and a video data signal to the component of the latter part of the serial receiver. Moreover, it is possible to supply a clock signal having no drifting caused by a temperature change to the component of the latter part of the serial receiver.

### BACKGROUND OF THE INVENTION

1. Field of the Invention

The present invention relates to a video apparatus having a serial receiver. More particularly, it relates to a video apparatus having a high-speed serial receiver, and capable of supplying a video signal and a clock to the component of the latter part of this serial receiver.

2. Description of the related art

With regard to a serial receiver, a rapid progress has been made in the achievement of high resolution and a high speed in recent years. For example, among serial receivers compliant with Transition Minimized Differential Signaling (T.M.D.S.) Standard, there is one having a transmission capability of dot clock 165 MHz. For details on the T.M.D.S. Standard, refer to Digital Visual Interface Revision 1.0 enacted by Digital Display Working Group (DDWG) on Apr. 2, 1999. A T.M.D.S. serial transmission path is composed of a video data transmission path of three channels (R, G, and B), and a synchronous clock transmission path of one channel. The video data and control signal of each color (8 bits) are encoded into 10-bit serial data with signal transition minimized by a T.M.D.S. transmitter, and transmitted as a differential serial signal with small signal amplitude. A T.M.D.S. receiver receives and decodes the video data of each color, and then outputs a video data signal including an 8-bit even number video data signal of each of RGB (QE{0-23}) and an odd number video data signal (QO{0-23}), and a control signal for a horizontal synchronous signal (HD), a vertical synchronous signal (VD), and a data enabling signal (DE). In addition, the T.M.D.S. receiver receives a synchronous clock, and outputs predetermined one of an Odd clock (OCLK) corresponding to the odd number video data QO{0-23}, and an Even clock (ECLK) having a phase different by 180° from that of the Odd clock (OCLK).

At the T.M.D.S. receiver corresponding to a dot clock 165 MHz, a 1-clock cycle becomes about 6 nsec. In such a high-speed serial receiver, the timing management of 3 nsec. or lower is necessary, considering data set-up time and data holding time. In the video apparatus having the conventional T.M.D.S. receiver, when timing was not matched between the video data signals (QE{0-23} and QO{0-23}) and the Odd clock (OCLK), a delaying device was installed to set timing by delaying the Odd clock (OCLK).

However, in such a conventional technology, drifting occurred in the delaying device when the ambient temperature of the delaying device changed. Consequently, it was difficult to maintain timing between the video data signal and the Odd clock (OCLK) in a proper state. In other words, although the-timing management of high accuracy was required, the timing was shifted even by a slight temperature change, causing malfunction.

To add various components to the video apparatus, it may be necessary to supply the clock of a frequency varied from component to component. For example, in the case of using a video processing circuit operated only by the main clock (MCLK) of a frequency, which is twice as much as that of the Odd clock (OCLK), the T.M.D.S. receiver operated on a two pixel mode cannot be used. Thus, a limitation is placed on usable components.

Furthermore, if the T.M.D.S. receiver is based on the two pixel mode, and the video processing circuit needs a differential clock, it is necessary to generate a differential clock (DCLK) including an Odd clock (OCLK) and its reversed clock, and supply the clock to the video processing circuit, by reversing the polarity of the Odd clock (OCLK) with a circuit such as an inverter. However, since phase shifting occurs because of operation delaying between two differential clocks when a differential clock (DCLK) is generated by the inverter circuit, it becomes extremely difficult to match timing with the video data signal. Also in this case, it is impossible to achieve a highly accurate timing adjustment, which is required.

### SUMMARY OF THE INVENTION

The present invention was made with the foregoing problems in mind, and it is an object of the invention to provide a video apparatus capable of optionally set timing for an input clock and a video data signal to the component of the latter part of a serial receiver.

It is another object of the invention to provide a video apparatus capable of supplying, as an input clock, a clock having no drifting caused by a temperature change, i.e., a stable clock not influenced by a surrounding environment, to the component of the latter part of a serial receiver.

It is yet another object of the invention to provide a video apparatus capable of supplying, as an input clock, any of a main clock and a differential clock to the component of the latter part of a serial receiver.

In order to achieve the foregoing object, in accordance with the invention, there is provided a video apparatus, comprising: a serial receiver for receiving, reproducing and outputting a synchronous clock, a control signal, and a signal containing video data; and a phase locked loop (PLL) for generating a differential clock having a phase different from that of the signal input from the serial receiver, and a main clock having a phase different from that of the signal input from the serial receiver, and a frequency twice as much as that of the differential clock.

The foregoing and other related objects and features will become apparent upon a reading of the following detailed description made based on the accompanying drawings, and new items specified in appended claims.

### BRIEF DESCRIPTION OF THE DRAWINGS

To facilitate the understanding of the drawings used in the detailed description of the invention, each drawing is now briefly described.

FIG. 1 is a block diagram illustrating an internal configuration of a video apparatus of the invention.

FIG. 2 is a schematic block diagram of an inside of a PLL.

FIG. 3 is a block diagram showing a video apparatus of the invention compliant with T.M.D.S. Standard.

FIG. 4 is a timing diagram between an Odd clock and a video data signal, or the like.

FIG. 5 is a timing diagram illustrating a relation among an Odd clock, a differential clock and a main clock.

FIG. 6 is a block diagram showing a video apparatus according to another embodiment of the invention.

FIG. 7 is a block diagram showing a video apparatus according to yet another embodiment of the invention.

### DETAILED DESCRIPTION OF THE PREFERRED EMBODIMENTS

Next, the preferred embodiments of the present invention will be described in detail with reference to the accompanying drawings. This section describes only the embodiments, but it in no way limits the interpretation of the invention to such embodiments.

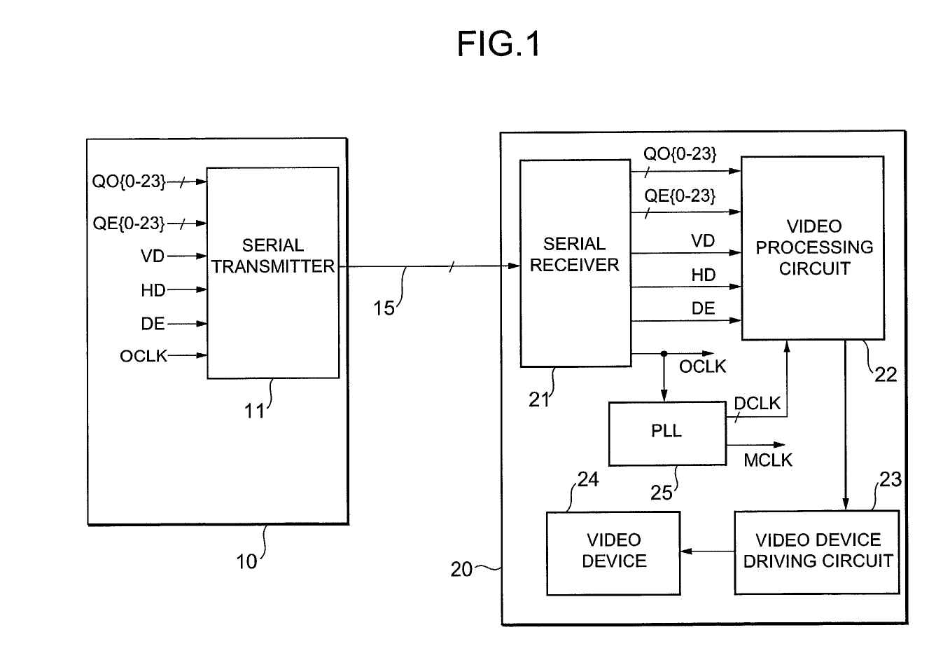

FIG. 1 is a block diagram showing the internal configuration example of the video apparatus of the invention. In FIG. 1, the video apparatus denoted at 20 comprises a serial receiver 21, a video processing circuit 22 as a component of the latter part of the serial receiver 21, a video device driving circuit 23, a video device 24, and a PLL 25.

The serial receiver 21 receives a synchronous clock, a control signal, and a signal containing video data serially transmitted from the serial transmitter 11 of a video apparatus 10 or the like, and generates (reproduces) each signal. In the example of FIG. 1, the received serial data is decoded, and vide data signals, i.e., an odd number video data signal (QO{0-23}) and an even number video data signal (QE{0-23}), and a control signal for a horizontal synchronous signal (HD), a vertical synchronous signal (VD), and a data enabling signal (DE), and an Odd clock (OCLK) are reproduced, and outputted.

For the serial receiver 21, any can be used as long as it can decode serial data and output each signal. For example, one can be selected from a serial receiver compliant with T.M.D.S. Standard, a serial receiver compliant with Low Voltage Differential Signaling (LVDS) Standard, a serial receiver compliant with Giga-bit Video Interface (GVIF) Standard, a serial receiver complaint with 292M Standard of Society of Motion Picture and Television Engineers (SMPTE), a serial receiver compliant with 259M Level C Standard, and so on.

The video processing circuit 22 includes an Application Specific Integrated Circuit (ASIC), generates gray-scale data of R, G and B in a form corresponding to the video device, a control signal for driving the video device 24, and so on, and output them to the video device driving circuit 23.

The video device driving circuit 23 drives video device 24 based on the input from the video processing circuit 22.

The video device 24 is a device, such as a Digital Micromirror Device (DMD), a Liquid Crystal DisPlay (LCD), a CRT, or the like, for displaying videos.

The PLL 25 generates, based on a signal input from the serial receiver 21, a differential clock (DCLK) having a phase different from that of the input signal, and a main clock (MCLK) having a phase different from that of the input signal, and a frequency twice as much as that of the differential clock.

Any signal input from the serial receiver to the PLL can be used, as long as it enables the PLL 25 to generate a main clock (MCLK) and a differential clock (DCLK) by PLL control. For example, one can be selected form a horizontal synchronous signal (HD), an Odd clock (OCLK), and an Even clock (ECLK).

As described above, any PLL 25 can be used as long as it can generate a differential clock (DCLK) and a main clock (MCLK). However, it should preferably be a circuit different from a clock recovery PLL installed in the serial receiver 21 to generate a clock. In other words, the PLL 25 should be a circuit provided independently of the PLL in the serial receiver 21. Accordingly, only by changing the setting of the PLL 25, the user can change the setting of a phase difference among a signal input from the serial receiver 21 to the PLL, a main clock (MCLK), and a differential clock (DCLK).

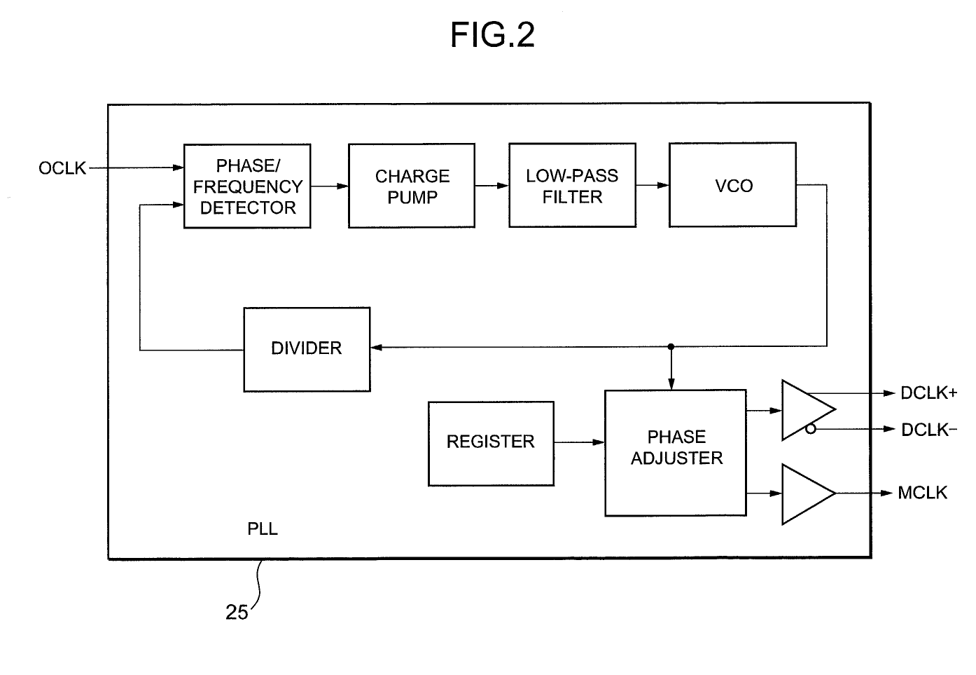

As the PLL 25, for example, an ICS 1523 made by Integrated Circuit Systems, Inc. (ICS) can be used. For details on the ICS 1523, refer a data sheet (ICS 1523 Rev S May 21, 1999) issued by of the ICS. FIG. 2 is schematic block diagram showing an example of the inside of the PLL 25. The PLL 25 includes a phase/frequency detector, a charge pump, a low-pass filter, a voltage controlled oscillator (VCO), and a divider, forming a PLL loop. The PLL 25 delays the output of the VCO by time corresponding to a value set in a register with a phase adjuster, and then outputs differential clocks (DCLK+, and DCLK−) and a main clock (MCLK) having a double frequency.

The delay time added with the phase adjuster can be adjusted by a unit delay step decided by dividing a clock cycle by a predetermined integer. In the ICS 1523, when a clock of 165 MHz is outputted as a main clock (MCLK), a phase can be adjusted by a step of about 0.4 ns, where one cycle is divided into sixteen.

Now, description will be made based on the example of the video apparatus compliant with the T.M.D.S. Standard.

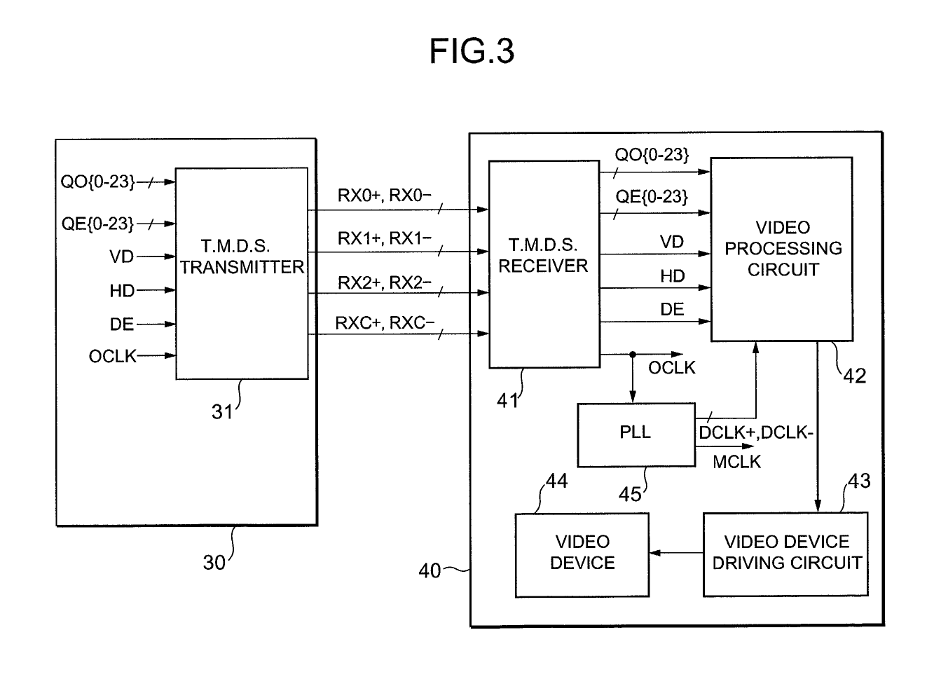

FIG. 3 is a block diagram showing the internal configuration of a video apparatus 40 according to an embodiment of the invention, which comprises a T.M.D.S. receiver 41 as the serial receiver of the T.M.D.S. Standard, and a PLL 45 independently installed outside the T.M.D.S. receiver 41.

As shown in FIG. 3, the video apparatus 40 specifically comprises the T.M.D.S. receiver 41, a video processing circuit 42, a video device driving circuit 43, a video device 44, and the PLL 45. the T.M.D.S. receiver 41, the video processing circuit 42, the video device driving circuit 43, the video device 44, and the PLL 45 respectively correspond to the serial receiver 21, the video processing circuit 22, the video device driving circuit 23, the video device 24, and the PLL 25 shown in FIG. 1.

The T.M.D.S. receiver 41 receives serial data generated by the T.M.D.S. transmitter 31 of a video apparatus 30. The serial data is transmitted, as one containing a differential signal (RX0+, RX0−) obtained by executing T.M.D.S. encoding processing for blue data, a differential signal (RX1+, RX1−) obtained by executing T.M.D.S. encoding processing for green data, and a differential signal (RX2+, RX2−) obtained by executing T.M.D.S. encoding processing for red data, through a 3-channel M.T.D.S. video data transmission path. The T.M.D.S. receiver 41 decodes the serial data received through the video data transmission path, and reproduces and outputs video data signals, i.e., an even number video data signal (QE{0-23}) and an odd number video data signal (QO{0-23}), and a control signal for a data enabling signal (DE), a horizontal synchronous signal (HD), and a vertical synchronous signal (VD). In addition, T.M.D.S. receiver 41 receives the differential clock signal (RXC+, RXC−) through a synchronous clock transmission path, and outputs an Odd clock (OCLK) corresponding to the odd number video data signal (QO{0-23}) by a clock recovery PLL installed inside. The T.M.D.S. receiver 41 of FIG. 3 is adapted to output the Odd clock (OCLK). However, instead of the Odd clock, it can output an Even clock having a phase different by 180° from that of the Odd clock phase to the change of the Odd clock. A general T.M.D.S. receiver is adapted to output either one of the Odd clock and the Even clock.

The PLL 45 receives the entry of the Odd clock (OCLK) from the serial receiver 41, executes PLL control and phase adjustment, and generates a main clock (MCLK) having a phase different from that of the Odd clock (OCLK) by a frequency twice as much as that of the Odd clock (OCLK), and a differential clock ((DCLK+, DCLK−) having a phase different from that of the Odd clock (OCLK) by a frequency equal to that of the Odd clock (OCLK). For example, at the time of UXGA 60 Hz, a main clock (MCLK) of 165 MHz and a differential clock (DCLK+, DCLK−) of 82.5 MHz are outputted from the PLL 45.

As described above with reference to the PLL 25 of FIG. 2, the user can optionally change the phases of the main clock (MCLK), the differential clock (DCLK+, DCLK−), and the Odd clock by changing the setting of PLL 45. Thus, it is possible to supply a main clock (MCLK) and a differential clock (DCLK+, DCLK−) having optimal phases to the components of the latter part of the serial receiver 41, i.e., the video processing circuit 42, the video device driving circuits 43, the video device 44, and so on. In addition, since a phase is set by a delay unit step, in which a clock cycle is divided, and the clock cycle is managed by PLL control so as to prevent fluctuation caused by a surrounding environment, drifting by a temperature change is greatly suppressed.

In FIG. 3, among the outputs of the PLL 45, the differential clock (DCLK+, DCLK−) is supplied to the video processing circuit 42. However, if the video processing circuit is operated only by the main clock (MCLK), the main clock only needs to be supplied instead of the differential clock (DCLK+, DCLK−).

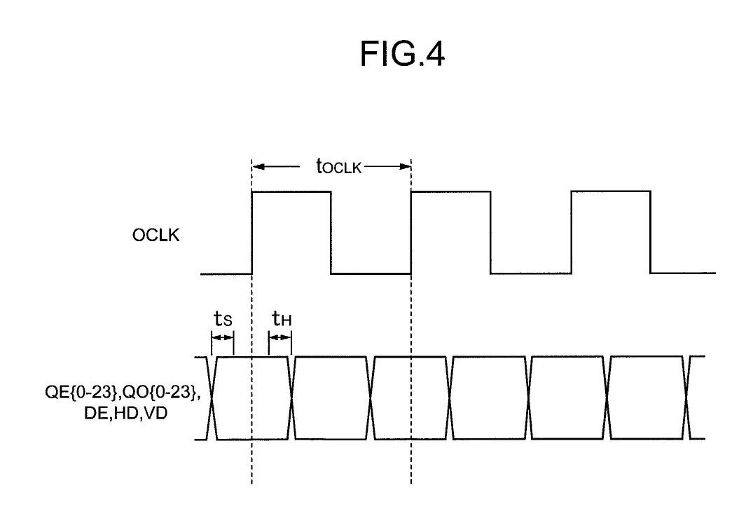

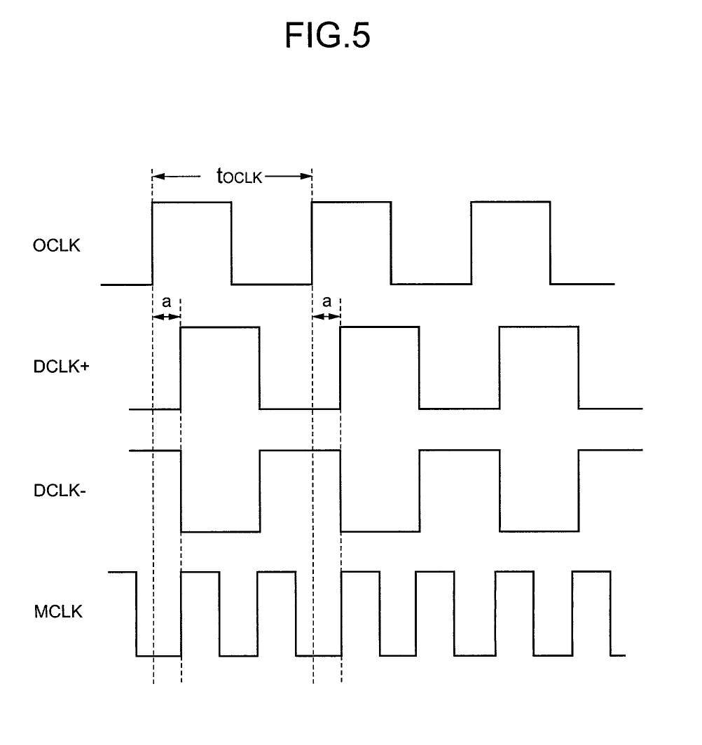

FIGS. 4 and 5 are timing diagrams, each showing the situation of PLL control by the PLL 45.

Specifically, FIG. 4 shows a relation between the video data signals (QE{0-23} and QO{0-23}) and the Odd clock (OCLK) obtained by decoding at the serial receiver 41.

As shown in FIG. 4, if the rising of the Odd clock (OCLK) is substantially in the center of adjacent change points of the video data signal, it is not necessary to execute phase adjustment by the PLL 45 because timing is proper. On the other hand, if the rising of the Odd clock (OCLK) during the period of data setup time tₛ, the video data signals (QE{0-23} and QO{0-23}) cannot be normally read in the video processing circuit 42 because timing is improper. To prevent such a situation, the PLL 45 adjusts the output clock signal to have a proper phase similar to that of the Odd clock (OCLK) of FIG. 4, and then supplies it to the video processing circuit 42. A similar operation is carried out when the rising of the Odd clock (OCLK) is during the period of data holding time t_{H}. In the drawing, tOCLK indicates one cycle of the Odd clock (OCLK) FIG. 5 shows a timing relation among the main clock (MCLK), the differential clock (DCLK+, DCLK−) and the Odd clock (OCLK) outputted from the PLL 45.

As shown in FIGS. 4 and 5, the PLL 45 can output a main clock (MCLK) and a differential clock (DCLK+, DCLK−) synchronized with the Odd clock (OCLK) by keeping a phase difference a, by subjecting the Odd clock (OCLK) to PLL control and phase adjustment processing.

By changing the setting of the phase a, the user can set timing of the video data signals (QE{0-23} and QO{0-23}) optimal for the circuit of the latter part of the serial receiver 41, for example the video processing circuit 42.

As can be understood from FIG. 4, any signal can be used by the PLL 45, as long as it has a cycle to be synchronized with the Odd clock (OCLK).

Preferably, the PLL 45 should be a circuit different from a clock recovery PLL installed in the serial receiver 41. In other words, the use of the circuit independent of the PLL in the serial receiver enables the user to change the setting of a phase difference among the Odd clock (OCLK), the main clock (MCLK), and the differential clock (DCLK+, DCLK−) only by changing the setting of the PLL 45.

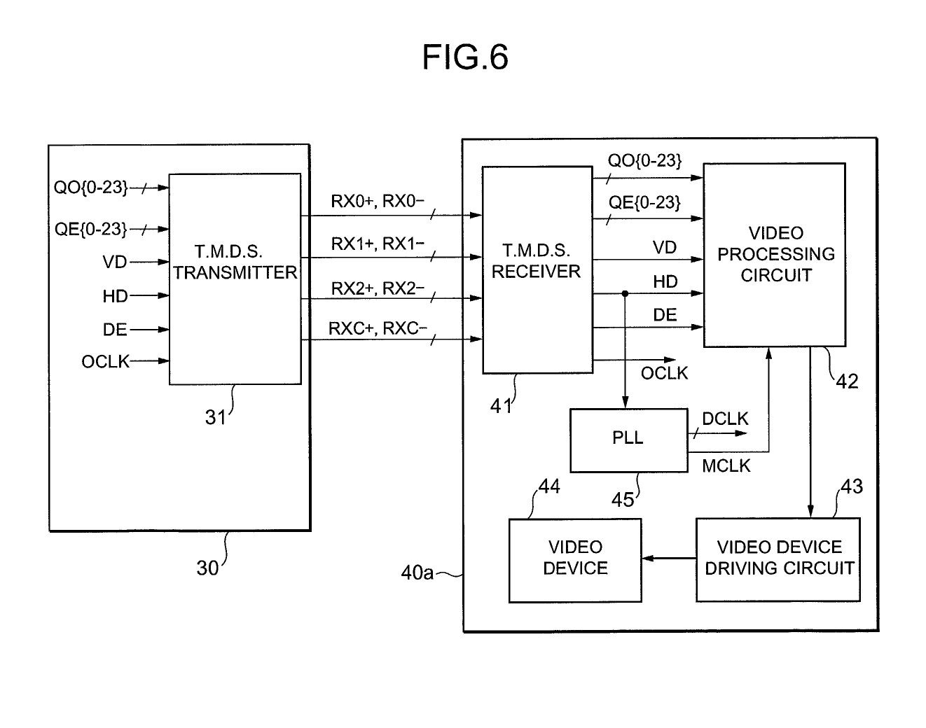

FIG. 6 is a block diagram showing a video apparatus according to another embodiment, where instead of the Odd clock (OCLK), a horizontal synchronous signal (HD) is input to the PLL 45. The video apparatus denoted at 40a is basically similar to the video apparatus 40 of FIG. 3, except for the fact that the entry to the PLL 45 is changed to a horizontal synchronous signal (HD), and that the clock signal supplied to the video processing circuit 42 is changed to a main clock (MCLK). As shown in FIG. 4, since the horizontal synchronous signal (HD) has a cycle to be synchronized with the Odd clock (OCLK), it can be used instead of the Odd clock (OCLK). In FIG. 6, if the video processing circuit 42 is operated by a differential clock, then the differential clock (DCLK+, DCLK−) needs only to be supplied instead of the main clock (MCLK).

Also in this embodiment, preferably, the PLL 45 should be a circuit different from a clock recovery PLL installed in the serial receiver 41. Only by changing the setting of PLL 45, the user can change the setting of a phase difference among the horizontal synchronous signal (HD), the main clock (MCLK), and the differential clock (DCLK+, DCLK−).

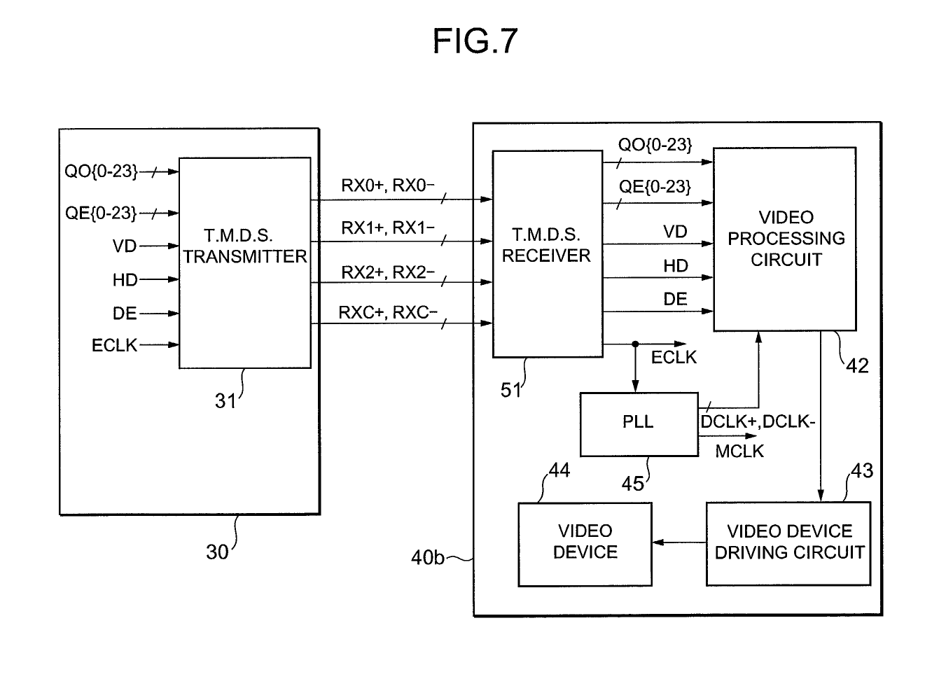

FIG. 7 is a block diagram showing a video apparatus according to yet another embodiment, where instead of the Odd clock (OCLK), an Even clock is input to the PLL 45. The video apparatus denoted at 40b is basically similar to the video apparatus 40, except for the fact that T.M.D.S. receiver 51 reproduces the Even clock (ECLK) while the T.M.D.S. receiver 41 reproduces the Odd clock, and that the entry to the PLL 45 is changed to the Even clock (ECLK). Since the Even clock (ECLK) is a clock signal having a cycle similar to that of the Odd clock (OCLK), and a phase different by 180° from that of the same, it can be used instead of the Odd clock (OCLK). In FIG. 7, if a video processing circuit 42 is operated only by a main clock, then the main clock (MCLK) needs only to be supplied instead of the differential clock (DCLK+, DCLK−).

Also in this embodiment, preferably, the PLL 45 should be a circuit different from a clock recovery PLL installed in the serial receiver 41. The use of the circuit independent of the PLL in the serial receiver enables the user to change the setting of a phase difference among the Even clock (ECLK), the main clock (MCLK), and the differential clock (DCLK+, DCLK−) only by changing the setting of the PLL 45.

As apparent from the foregoing, according to the present invention, since the video apparatus comprises: the serial receiver; and the PLL for generating a differential clock having a phase different from that of a signal input from the serial receiver, and a main clock having a phase different from that of the signal input from the serial receiver, and a frequency twice as much as that of the differential clock, based on the signal input from the serial receiver, it is possible to supply a clock signal adjusted to optimal timing to the components of the latter part of the serial receiver.

The use of the PLL can cancel any changes in the phase of the clock signal caused by a change in the ambient temperature.

In addition, according to the invention, the use of the PLL independent of the PLL installed in the serial receiver makes it possible to change a phase difference among a signal input from the serial receiver, a main clock, and a differential clock only by changing the setting of this PLL.

According to the invention, since a main clock can be generated, it is possible to install a component capable of receiving only the main clock, such as a video processing circuit, in the latter part of the serial receiver.

Since a differential clock is generated by using the PLL, no extra phase difference occurs, different from the case of generating a differential clock by an inverter or the like. Thus, it is possible to set optimal timing with a video.

Thus, in the video apparatus of the present invention, it is possible to prevent deviation between the Odd clock and video data signal timing, which has occurred in the conventional art. It is also possible to supply a stable clock not influenced by a surrounding environment to the component of the latter part of the serial receiver.

What is claimed is:

1. A video apparatus comprising:
a serial receiver for receiving, reproducing and outputting a serially transmitted signal; and
a phase locked loop (PLL) for generating a differential clock having a phase different from that of said signal and a main clock having a phase different from that of said signal and a frequency twice as much as that of said differential clock on the basis of said signal input from said serial receiver.

2. A video apparatus according to claim 1, wherein the phase of said main clock is coincident with that of said differential clock.

3. A video apparatus according to claim 2, wherein said PLL is provided independently of a PLL installed in said serial receiver.

4. A video apparatus according to claim 1, wherein said signal is a horizontal synchronous signal.

5. A video apparatus according to claim 1, wherein said signal is an Odd clock signal.

6. A video apparatus according to claim 1, wherein said signal is an Even clock signal.
